(19) United States
(12) Patent Application Publication
(10) Pub. No.: US 2026/0172037 A1
(43) Pub. Date: Jun. 18, 2026

(54) PHASE-LOCKED LOOP WITH MODULATOR

(71) Applicant: Robert Bosch GmbH, Stuttgart (DE)

(72) Inventors: Michael Wickert, Dresden (DE); Reiner Schnitzer, Reutlingen (DE)

(21) Appl. No.: 19/410,322

(22) Filed: Dec. 5, 2025

(30) Foreign Application Priority Data
Dec. 17, 2024 (DE) 10 2024 212 024.3

(51) Int. Cl. H03L 7/093; H03L 7/099

(52) U.S. Cl. CPC H03L 7/093; H03L 7/099

(57) ABSTRACT

A phase-locked loop. The phase-locked loop includes: a phase ascertaining unit for detecting a phase difference between a reference signal and a feedback signal, and outputting a measurement signal representing the phase difference; a phase deviation ascertaining unit for generating an error signal from the measurement signal and a target signal; a loop filter for filtering the error signal; a modulator unit for modulating the filtered error signal, and generating a tune signal, and an oscillator for generating an output signal from the tune signal. A feedback signal derived from the output signal of the phase-locked loop is supplied to the phase ascertaining unit. The modulator unit has a modulator and a scrambler installed downstream. The modulator unit has an impairment module configured to ascertain a signal impairment from metadata of the scrambler and from predefined calibration data, and is configured to feed signal impairments back to the modulator.

### FIELD

The present invention relates to a phase-locked loop. The phase-locked loop has a modulator. The configuration of the phase-locked loop and the modulator allows for simplified calibration.

### BACKGROUND INFORMATION

In digital phase-locked loops, it is conventional, for example, to use delta-sigma modulation. For this purpose, calibration parameters are typically provided to model the behavior of the oscillator of the phase-locked loop. The calibration parameters determine the accuracy of the modulation. The higher the required precision of the modulation, the greater the number of calibration parameters typically required.

### SUMMARY

According to an example embodiment, a phase-locked loop according to the invention has a modulator, eliminating the need for a high-precision oscillator model, i.e., the number of calibration parameters is small. This is achieved through the combined use of a relatively simple oscillator model and feedback.

The phase-locked loop has a phase ascertaining unit, a phase deviation ascertaining unit, a loop filter, a modulator unit and an oscillator, which is in particular a voltage-controlled oscillator. The phase ascertaining unit is used to detect a phase difference between a reference signal and a feedback signal and to output a measurement signal φₘₑₐₛ representing the phase difference. The phase deviation ascertaining unit is used to generate an error signal φₑᵣᵣ from the measurement signal φₘₑₐₛ and a target signal φ_{tgt}. The loop filter is provided to filter the error signal φₑᵣᵣ. The modulator unit is used to modulate the filtered error signal and to generate a tune signal, with the oscillator being configured to generate an output signal from the tune signal.

The phase ascertaining unit receives a feedback signal derived from an output signal of the phase-locked loop. Thus, a control loop is formed that regulates a phase of the output signal.

The modulator unit comprises a modulator and a scrambler installed downstream of the modulator. The scrambler is used primarily for mismatch shaping and/or transition control. The scrambler is trained to provide metadata that describe basic properties of the selection of active elements of the oscillator.

The modulator unit also comprises an impairment module configured to ascertain a signal impairment from the scrambler metadata and from predefined calibration data. Additionally, the impairment module is configured to feed signal impairments back to the modulator. Thus, the modulator can take the impairments of the active elements into account in the next modulation step.

This allows the effects of many detailed impairments to be taken into account without the need for highly complex or even impossible oscillator models. The phase-locked loop thus exhibits high modulation accuracy while being cost-effective and simple to implement. Simple calibration steps allow for the identification of individual parameters to describe the impairments without requiring explicit solvability and reversibility of the global oscillator model.

Preferred developments of the invention are disclosed herein.

According to an example embodiment, preferably, the modulator unit has a model of the oscillator installed upstream of the modulator. The model is based on the predefined calibration data. Thus, simple impairments can be taken into account via the model, which is easy to implement. In particular, the reversibility/solvability of the model must be maintained, so that the number of parameters is limited. This is particularly advantageous because the impairments caused by the scrambler result are only taken into account after its application, so that only corrective measures can be taken. Therefore, it is advantageous to include the main dependencies, in particular first-order dependencies, in a simple forward model and install it upstream of the modulator as the model.

The model is particularly advantageously configured to predict, for various tune signals, a frequency and/or a phase response of the output signal generated by the oscillator. The prediction is relatively rough, as preferably only the main dependencies, as described above, are taken into account. This ensures, in particular, that the model is easy to deploy.

In particular, the model disregards factors that can only be represented in a complex manner or not at all. Preferably, the model disregards influences of hardware gradients, in particular capacitance gradients, and/or thermal conditions and/or amplitude variations and/or runtime differences on the behavior of the oscillator.

According to an example embodiment, the modulator is in particular a delta-sigma modulator. This allows, in particular, the creation of a digital tune word as a tune signal. A digital phase-locked loop is particularly advantageous for the entire phase-locked loop.

The phase-locked loop preferably has a specification unit. The specification unit is configured to generate the target signal φ_{tgt}. The specification unit is also configured to output information about the target signal φ_{tgt} to the modulator. In one possible configuration for generating FMCW (frequency-modulated-continuous-wave) frequency ramps, the specification unit has a ramp generator that is used to generate a ramp signal. This is processed via an integrator to produce the target signal φ_{tgt}. The ramp signal is in particular also output to the modulator.

The phase ascertaining unit preferably has a digital-to-time converter and a phase measurement unit connected in series. The phase measurement unit is, for example, a time-to-digital converter. The digital-to-time converter is, in particular, installed upstream of the phase measurement unit. A reference signal can be supplied to the digital-to-time converter, and an output of the digital-to-time converter can be supplied to the phase measurement unit. In particular, the output of the digital-to-time converter can be supplied to the phase measurement unit as a clock signal. The digital-to-time converter is used in particular to apply a dither to the reference signal due to the relatively coarse quantization steps of the phase measurement unit, in particular the time-to-digital converter. The feedback signal can also be supplied to the phase measurement unit. In this way, the measurement signal φₘₑₐₛ can be obtained simply and reliably.

### BRIEF DESCRIPTION OF THE DRAWINGS

In the following, exemplary embodiments of the invention are described in detail with reference to the figures.

FIG. 1 is a schematic representation of a phase-locked loop according to an exemplary embodiment of the invention.

FIG. 2 is a schematic representation of a modulator unit of the phase-locked loop according to the exemplary embodiment of the invention.

FIG. 3 is a schematic representation of an oscillator of the phase-locked loop according to the exemplary embodiment of the invention.

### DETAILED DESCRIPTION OF EXAMPLE EMBODIMENTS

Preferably, identical components, elements, and/or units are provided with identical reference signs in all figures.

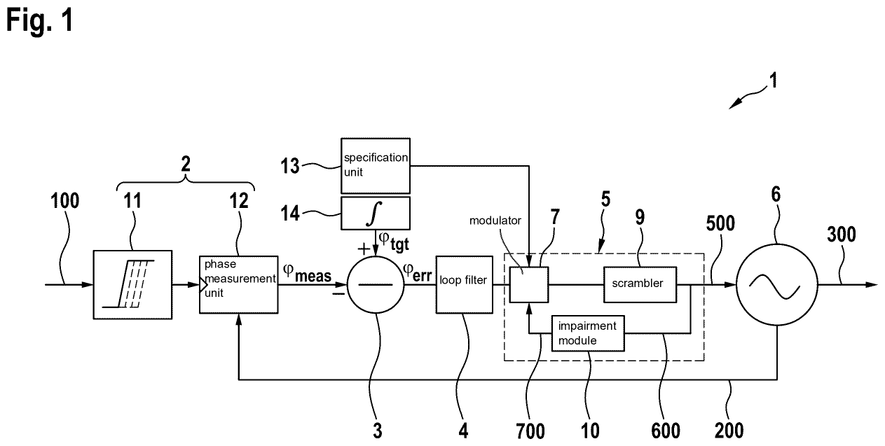

FIG. 1 schematically shows a phase-locked loop 1 (PLL). In particular, the phase-locked loop 1 is a digital phase-locked loop (DPLL) or an all-digital phase-locked loop (ADPLL).

The phase-locked loop 1 is used to track a phase of an oscillator 6 according to the phase of a reference signal 100. In the exemplary embodiment shown, a digitally controlled oscillator 6 (DCO) is provided. The phase-locked loop 1 has a phase ascertaining unit 2, which is configured to detect a phase difference between a reference signal 100 and a feedback signal 200 and to output a measurement signal φₘₑₐₛ representing the phase difference.

The phase ascertaining unit 2 has a digital-to-time converter 11 and a phase measurement unit 12 connected in series. The phase measurement unit 12 is, for example, a time-to-digital converter.

The digital-to-time converter 11 is installed upstream of the phase measurement unit 12 and is used to apply a dither to the reference signal 100, which can be supplied to the digital-to-time converter 11. The phase measurement unit 12 can be supplied with an output of the digital-to-time converter 11, whereby the applied dithering is advantageous for taking into account the relatively coarse quantization steps of the time-to-digital converter as the phase measurement unit 12. The feedback signal 200 can also be supplied to the phase measurement unit 12.

The phase-locked loop 1 also has a modulator unit 5, whereby the modulation in the illustrated exemplary embodiment is applied as two-point modulation to avoid deflection of the loop filter. For this purpose, a specification unit 13, 14 is provided, which is configured to generate a target signal φ_{tgt}. In the illustrated exemplary embodiment, the specification unit 13, 14 has a ramp generator 13 which is used to generate a ramp signal. This is processed via an integrator 14 to produce the target signal φ_{tgt}. The ramp signal is in particular also output to the modulator unit 5.

A phase deviation ascertaining unit 3 is configured to generate an error signal φₑᵣᵣ from the measurement signal φₘₑₐₛ and the target signal φ_{tgt}. By taking the target signal φ_{tgt} into account, modulation takes place at a first point in order to achieve the aforementioned two-point modulation.

The phase-locked loop 1 has a loop filter 4 for filtering the error signal φₑᵣᵣ, wherein the output of the loop filter 4 can be fed to the modulator unit 5. The loop filter 4 is, for example, a digital loop filter (DLF).

The modulator unit 5 is configured to modulate the filtered error signal and to generate a tune signal 500. The oscillator 6 can be controlled by the tune signal 500, wherein the oscillator 6 is configured to generate an output signal 300 from the tune signal 500. The feedback signal 200 supplied to the phase ascertaining unit 2 is derived from the output signal 300 of the phase-locked loop 1.

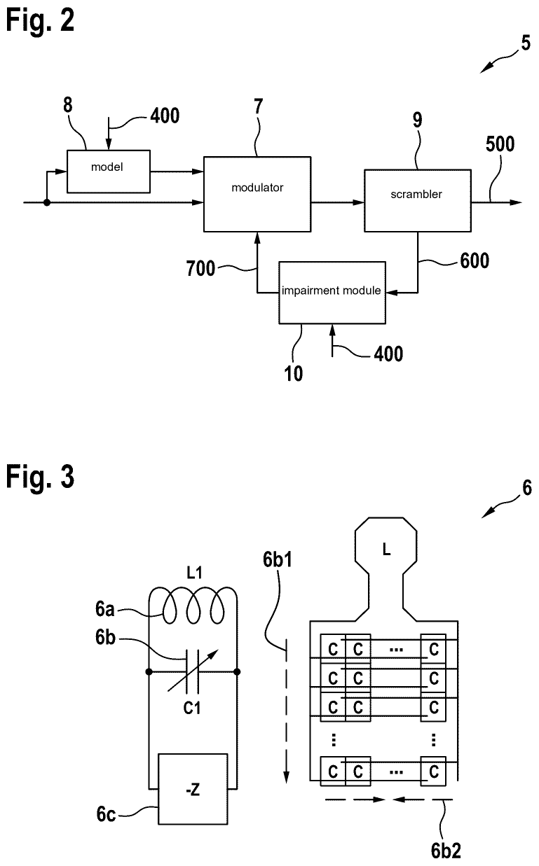

The modulator unit 5 represents a second point of the two-point modulation. An exemplary modulator unit 5 is shown schematically in FIG. 2. The modulator unit 5 has a modulator 7 and a scrambler 9 installed downstream of the modulator 7. The modulator 7, for example, is a delta-sigma modulator. The scrambler 9 is used primarily for mismatch shaping and/or transition control. Thus, the result of the scrambler defines the selection of active elements of the oscillator 6. The scrambler 9 is trained to provide metadata 600 that describe basic properties of the selection of active elements of the oscillator 6.

The modulator unit 5 has an impairment module 10. The impairment module 10 is used to calculate a signal impairment from the metadata 600 of the scrambler 9 and from predefined calibration data 400. The signal impairments 700 are fed back to the modulator 7.

Furthermore, the modulator unit 5 has a simplified model 8 of the oscillator 6 installed upstream of the modulator 7. The model 8 is based on the predefined calibration data 400, disregarding the effects resulting from the scrambler selection. In particular, the model 8 is configured to predict, for various tune signals 500, a frequency and/or a phase response of the output signal 300 generated by the oscillator 6. Therefore, this is a forward model to take simple impairments into account. The intention is that the model 8 will be implemented simply. The combination of the model 8, the scrambler 9 and the impairment module 10 results in precise modulation, eliminating the need for a complex or even impossible model 8.

To keep the model 8 simple, it disregards, for example, influences of hardware gradients, in particular capacitance gradients, and/or thermal conditions and/or amplitude variations and/or runtime differences on the behavior of the oscillator 6. This makes the model 8 easy to implement. The aforementioned influences can nevertheless be taken into account in the modulation via the scrambler 9 and the impairment module 10.

FIG. 3 shows an exemplary implementation of the oscillator 6 of the phase-locked loop 1 according to the exemplary embodiment of the invention. A schematic circuit diagram is shown on the left, and a schematic diagram of a configuration of the oscillator 6 is shown on the right. The oscillator 6 is an LC oscillator which has an inductance 6a and a capacitance 6b as well as a delay 6c. This oscillator 6 has different capacitance gradients 6b1, 6b2 along the tuning array. These lead to impairments, but cannot be represented by the model 8, or only with difficulty. Therefore, the influence of these capacitance gradients 6b1, 6b2 remains disregarded in the model 8. Instead, a correction is made using the scrambler 9 and the impairment module 10 within the framework of the above-described feedback.

1-7. (canceled)

8. A phase-locked loop, comprising:
a phase ascertaining unit configured to detect a phase difference between a reference signal and a feedback signal and to output a measurement signal representing the phase difference;
a phase deviation ascertaining unit configured to generate an error signal from the measurement signal and a target signal;
a loop filter configured to filter the error signal;
a modulator unit configured to modulate the filtered error signal and to generate a tune signal; and
an oscillator configured to generate an output signal from the tune signal;
wherein a feedback signal derived from the output signal of the phase-locked loop is supplied to the phase ascertaining unit;
wherein the modulator unit includes a modulator, and a scrambler installed downstream of the modulator; and
wherein the modulator unit includes an impairment module configured to ascertain a signal impairment from metadata of the scrambler and from predefined calibration data, and configured to feed signal impairments back to the modulator.

9. The phase-locked loop according to claim 8, wherein the modulator unit includes a model of the oscillator installed upstream of the modulator, wherein the model is based on the predefined calibration data.

10. The phase-locked loop according to claim 9, wherein the model is configured to predict, for various tune signals), a frequency and/or a phase response of the output signal generated by the oscillator.

11. The phase-locked loop according to claim 10, wherein the model disregards: (i) influences of hardware gradients including capacitance gradients and/or (ii) thermal conditions and/or (iii) amplitude variations and/or (iv) runtime differences on a behavior of the oscillator.

12. The phase-locked loop according to claim 8, wherein the modulator is a delta-sigma modulator.

13. The phase-locked loop according to claim 8, further comprising:
a specification unit configured to generate the target signal, wherein the specification unit is also configured to output information about the target signal to the modulator.

14. The phase-locked loop according to claim 8, wherein the phase ascertaining unit includes has a digital-to-time converter and a phase measurement unit connected in series, wherein the reference signal is supplied to the time-to-digital converter, and wherein an output of the digital-to-time converter, and the feedback signal, are supplied to the phase measurement unit.
